(19) United States
(12) Patent Application Publication
(10) Pub. No.: US 2012/0237723 A1
(43) Pub. Date: Sep. 20, 2012

(54) FILM MEMBER, FILM MOLDED PRODUCT, FILM MEMBER PRODUCING METHOD, AND FILM MOLDED PRODUCT PRODUCING METHOD

(75) Inventor: Kenji WADA, Fujimi (JP)

(73) Assignee: SEIKO EPSON CORPORATION, Tokyo (JP)

(21) Appl. No.: 13/410,809

(22) Filed: Mar. 2, 2012

(30) Foreign Application Priority Data
Mar. 15, 2011 (JP) 2011-056256

(51) Int. Cl. B32B 3/24; B29C 45/14; B32B 3/10; H05K 3/10; C01B 31/00

(52) U.S. Cl. 428/138; 428/209; 427/97.3; 264/272.11; 977/742

(57) ABSTRACT

A film member and a film molded product are disclosed that include a film layer, a decorative layer having a predetermined image, a metal wiring layer having a metal wiring, and a shape retaining layer.

### BACKGROUND

1. Technical Field

The present invention relates to a film member, a film molded product, a film member producing method, and a film molded product producing method.

2. Related Art

A decorative film is known that includes, for example, a protective layer, a color-containing adhesive layer, and a base layer. A plastic molded article produced by molding the decorative film by inmolding is also known (see JP-A-2005-125680).

The plastic molded article is used for, for example, the automobile control panel (console) incorporating various switches, and the exterior of electronic devices. The inside of these control panels and exteriors is a dense network of electric wires to accommodate the development of sophisticated electronics. This is problematic because it lowers the freedom of design.

### SUMMARY

An advantage of some aspects of the invention is to solve at least part of the foregoing problem, and the invention can be realized by the following aspects and application examples.

### APPLICATION EXAMPLE 1

A film member according to this application example includes: a film layer; a decorative layer having a predetermined image; a metal wiring layer having a metal wiring; and a shape retaining layer.

According to this configuration, the film member includes a decorative layer and a metal wiring layer. While the decorative layer provides the visual cosmetic effect, the metal wiring layer enables electrical interconnections. Further, for example, formation of a three-dimensional wiring, difficult to achieve with the related art, can easily be realized by molding the film member. In this case, enabling electrical interconnections in, for example, the control panel of automobiles makes it possible to save the internal electric wires, and improve the freedom of design.

### APPLICATION EXAMPLE 2

This application example of the invention is directed to the film member according to the foregoing application example including: the film layer; the decorative layer formed on the film layer; an adhesive layer formed on the decorative layer; the shape retaining layer disposed on the adhesive layer; and the metal wiring layer formed on the shape retaining layer.

According to this configuration, the decorative layer and the metal wiring layer can be realized as a three-dimensional molded product.

### APPLICATION EXAMPLE 3

This application example of the invention is directed to the film member according to the foregoing application example including: the film layer; the decorative layer formed on the film layer; a first adhesive layer formed on the decorative layer; a light-shielding layer formed on the first adhesive layer; a second adhesive layer formed on the light-shielding layer; the metal wiring layer formed on the second adhesive layer; and the shape retaining layer formed on the metal wiring layer.

According to this configuration, the decorative layer and the metal wiring layer can be realized as a three-dimensional molded product.

### APPLICATION EXAMPLE 4

This application example of the invention is directed to the film member according to the foregoing application example, wherein the metal wiring layer of the film member is formed using a carbon nanotube.

According to this configuration, a film member having high electric conductivity can be obtained.

### APPLICATION EXAMPLE 5

This application example of the invention is directed to the film member according to the foregoing application example, wherein the metal wiring of the metal wiring layer has a mesh shape.

According to this configuration, the stress exerted on the metal wiring in the stretched film member can be relieved to prevent the wires from being cut.

### APPLICATION EXAMPLE 6

A film molded product according to this application example includes: the film member; and a molded resin layer inmolded with the film member.

According to this configuration, a three-dimensional molded product can be provided that includes a decorative layer and a metal wiring layer. In this way, it is possible to save the internal electric wires and improve the freedom of design in, for example, the control panel of automobiles.

### APPLICATION EXAMPLE 7

This application example of the invention is directed to the film molded product according to the foregoing application example including a terminal guide hole that extends from a surface of the molded resin layer to a surface of the metal wiring layer.

According to this configuration, an electrical interconnection can easily be provided through the terminal guide hole that extends from the surface of the molded resin layer to the surface of the metal wiring layer.

### APPLICATION EXAMPLE 8

This application example of the invention is directed to the film molded product according to the foregoing application example including a terminal guide hole that extends from a surface of the film layer to a surface of the metal wiring layer.

According to this configuration, an electrical interconnection can easily be provided through the terminal guide hole that extends from the surface of the film layer to the surface of the metal wiring layer.

### APPLICATION EXAMPLE 9

A film member producing method according to this application example includes: forming a predetermined image on a film layer to form a decorative layer; and forming a metal wiring to form a metal wiring layer.

According to this configuration, the film member includes a decorative layer and a metal wiring layer. While the decorative layer provides the visual cosmetic effect, the metal wiring layer enables electrical interconnections. Further, for example, formation of a three-dimensional wiring, difficult to achieve with the related art, can easily be realized by molding the film member. In this case, enabling electrical interconnections in, for example, the control panel of automobiles makes it possible to save the internal electric wires, and improve the freedom of design.

### APPLICATION EXAMPLE 10

A film molded product producing method according to this application example includes: forming a molded resin layer by inmolding, using the film member produced by the film member producing method.

According to this configuration, a three-dimensional molded product can be provided that includes a decorative layer and a metal wiring layer. In this way, it is possible to save the internal electric wires and improve the freedom of design in, for example, the control panel of automobiles.

### BRIEF DESCRIPTION OF THE DRAWINGS

The invention will be described with reference to the accompanying drawings, wherein like numbers reference like elements.

FIG. 1 is a cross sectional view illustrating a configuration of a film member according to First Embodiment.

FIG. 2 is a schematic view illustrating an example of a metal wiring pattern of the film member according to First Embodiment.

FIGS. 3A to 3D are step diagrams representing a film member producing method according to First Embodiment.

FIG. 4 is a cross sectional view illustrating a configuration of a film molded product according to First Embodiment.

FIGS. 5A to 5C are step diagrams representing a film molded product producing method according to First Embodiment.

FIG. 6 is a cross sectional view illustrating a configuration of a film member according to Second Embodiment.

FIGS. 7A to 7E are step diagrams representing a film member producing method according to Second Embodiment.

FIG. 8 is a cross sectional view illustrating a configuration of a film molded product according to Second Embodiment.

FIGS. 9A to 9C are step diagrams representing a film mold product producing method according to Second Embodiment.

### DESCRIPTION OF EXEMPLARY EMBODIMENTS

Embodiments of the invention are described below with reference to the accompanying drawings. Note that the sizes of the layers and various members shown in the drawings are not to scale to make them recognizable.

### First Embodiment

### Configuration of Film Member

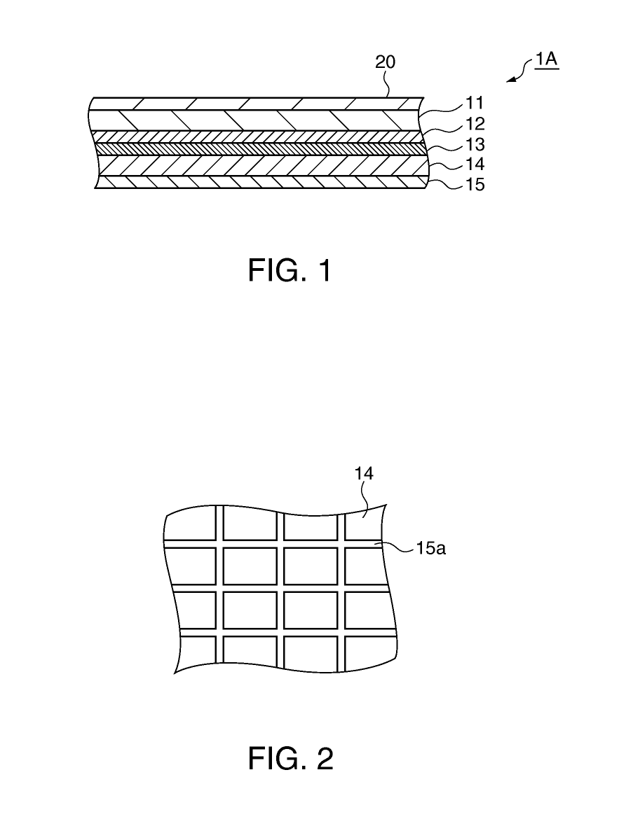

The configuration of the film member according to First Embodiment is described first. FIG. 1 is a cross sectional view illustrating the configuration of the film member according to First Embodiment. As illustrated in FIG. 1, a film member 1A includes a film layer 11, a decorative layer 12 having a predetermined image, a metal wiring layer 15 having a metal wiring, and a backing sheet 14 as a shape retaining layer.

More specifically, the film member 1A includes the film. layer 11, the decorative layer 12 formed on the film. layer 11, an adhesive layer 13 formed on the decorative layer 12, the backing sheet 14 disposed on the adhesive layer 13, and the metal wiring layer 15 formed on the backing sheet 14. In the present embodiment, a protective layer 20 that protects the film layer 11 is provided on a surface of the film layer 11.

The film layer 11 is configured from a transparent thermoplastic resin having a flat, smooth surface. As used herein, “transparent” means that the layer allows the decorative layer 12 to be seen through it. Accordingly, the film layer 11 maybe a colorless transparent layer, or a colored transparent layer. The film layer 11 is, for example, about 10 to 500 μm. Examples of the thermoplastic resin include acrylic resin, polyolefinic resin, polyester resin, polycarbonate resin, polyamide resin, polystyrene, AS (acrylonitrile-styrene copolymer) resin, polyvinyl chloride, vinyl chloride-vinyl acetate copolymer, used either alone or as a mixture of two or more. The protective film 20 formed on the film layer 11 in the present embodiment may be omitted. In this case, a lubricant such as a hydrocarbon lubricant and a fatty acid lubricant may be added to the film layer 11. In this way, the abrasion resistance and other layer properties can be maintained.

The decorative layer 12 is provided to improve decorative effects with images such as graphics and pictures. For example, the decorative layer 12 has woodgrain patterns, pebble patterns, sand patterns, tile patterns, brick patterns, fabric grain patterns, leather texture patterns, characters, symbols, graphics, and geometric patterns, appropriately formed either individually or in combination. The decorative layer 12 can be formed by using, for example, an inkjet method. In this case, UV curable ink is applied onto the film layer 11 in droplets through a discharge head. The applied UV curable ink is then irradiated with ultraviolet light to be fused on the film layer 11. The ink used in the inkjet method is not limited to UV curable ink, and may be, for example, IR curable or visible-light curable ink. In this case, a light source suited for the curing of each ink is used. Further, the ink maybe aqueous ink or solvent ink. Aside from the inkjet method, other methods, for example, such as gravure printing, letterpress printing, screen printing, offset printing, and flexography may be appropriately used.

The backing sheet 14 is provided to retain the molded shape. For example, acrylic resin, polyolefinic resin, polyester resin, polycarbonate resin, polyamide resin, polystyrene, AS (acrylonitrile-styrene copolymer) resin, polyvinyl chloride, and vinyl chloride-vinyl acetate copolymer are used either alone or in a combination of two or more. The backing sheet 14 may be made from ABS (acrylonitrile-butadiene-styrene copolymer) when no transparency is required.

The metal wiring layer 15 is a layer with a metal wiring. The metal wiring layer 15 may be formed by using, for example, an inkjet method. In this case, a functional liquid containing conductive fine particles is applied onto the backing sheet 14 by being discharged in droplets. The functional liquid is then solidified into a metal wiring. The conductive fine particles have a particle diameter of from several nanometers to several ten nanometers, and is made of, for example, metals such as silver, gold, copper, platinum, palladium, rhodium, osmium, ruthenium, iridium, iron, tin, cobalt, nickel, chromium, titanium, tantalum, tungsten, and indium, or alloys of these metals. As used herein, solidifying the functional liquid is to fuse the conductive fine particles contained in the functional liquid to make the metal wiring conductive.

The metal wiring may be formed using carbon nanotubes. Carbon nanotubes have high electric conductivity and excellent mechanical characteristics, and can be used to provide a high-quality film member, and a high-quality molded product.

Aside from the inkjet method, the metal wiring layer 15 can be formed by appropriately using, for example, gravure printing, letterpress printing, screen printing, offset printing, and flexography.

FIG. 2 is a schematic view illustrating an example of the metal wiring pattern of the film member according to First Embodiment. As illustrated in FIG. 2, a metal wiring 15a of the metal wiring layer 15 has a mesh shape (meshed). In this way, for example, the exerted stress in the stretched film member during the molding process can be relieved, and the metal wiring 15a can be prevented from breaking. Note that, for example, dimensions such as the width, thickness, the density of the mesh of the metal wiring 15a can be appropriately set, taking into account factors such as the position and the molded site of the metal wiring 15a.

### Film Member Producing Method

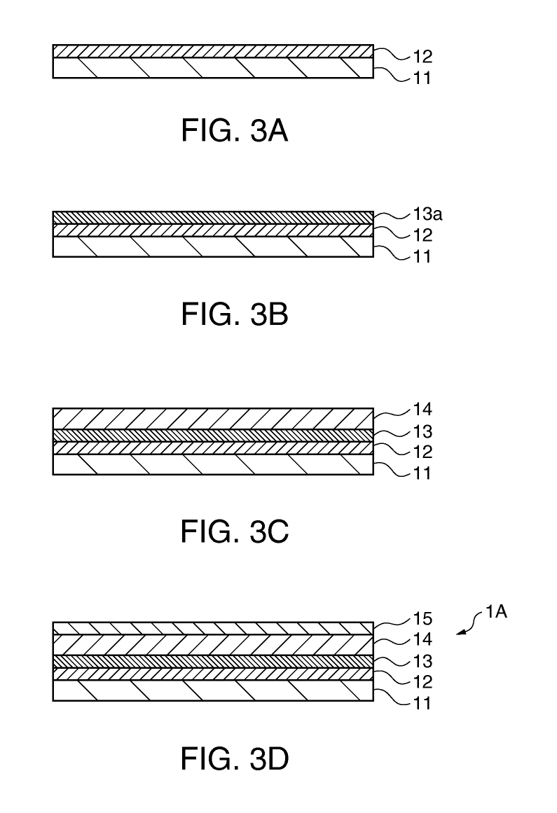

The film member producing method according to First Embodiment is described below. FIGS. 3A to 3D are step diagrams representing the film member producing method according to First Embodiment. As represented in FIGS. 3A to 3D, the film member producing method includes a decorative layer forming step of forming a predetermined image on the film layer, and a metal wiring layer forming step of forming a metal wiring. Each step is described below in detail.

In the decorative layer forming step (FIG. 3A) , the decorative layer 12 is formed on the film layer 11. For example, a functional liquid is applied onto the film layer 11 by being discharged toward the film layer 11 in droplets, using an inkjet method. The applied functional liquid is then solidified to form the decorative layer 12. Note that the method used to form the decorative layer 12 is not limited to an inkjet method, and, for example, methods such as gravure printing, letterpress printing, screen printing, offset printing, and flexography may be appropriately used.

In the adhesive coating step (FIG. 3B), an adhesive 13a is applied onto the decorative layer 12.

Thereafter, in the backing sheet disposing step (FIG. 3C), the backing sheet 14 is disposed on the adhesive 13a, and the adhesive 13a is solidified to form the adhesive layer 13 and dispose the backing sheet 14 on the adhesive layer 13.

In the next metal wiring layer forming step (FIG. 3D), a metal wiring is formed on the backing sheet 14. For example, a conductive fine particle-containing functional liquid is applied onto the backing sheet 14 by being discharged toward the film layer 11 in droplets, using an inkjet method. The applied functional liquid is then solidified to form the metal wiring. Alternatively, a carbon nanotube-containing functional liquid may be discharged in droplets, and solidified to form the metal wiring. Further, in the metal wiring layer forming step, the metal wiring 15a of a mesh shape may be formed, as illustrated in FIG. 2. Note that the method used to form the decorative layer 12 is not limited to the inkjet method, and, for example, methods such as gravure printing, letterpress printing, screen printing, offset printing, and flexography may be appropriately used.

The film member 1A is formed after these steps (see FIG. 1).

### Configuration of Film Molded Product

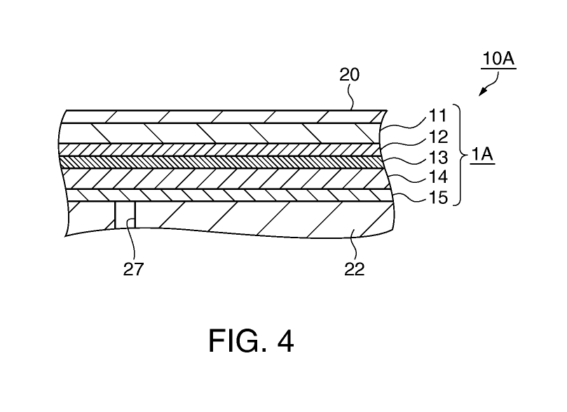

The configuration of the film molded product according to First Embodiment is described below. FIG. 4 is a cross sectional view illustrating the configuration of the film molded product according to First Embodiment. As illustrated in FIG. 4, a film molded product 10A includes the film member 1A, and a molded resin layer 22 inmolded with the film member 1A. In the present embodiment, the molded resin layer 22 is formed so as to cover the metal wiring layer 15. The configuration of the film member 1A is as described with reference to FIG. 1, and will not be described further.

The molded resin layer 22 is configured from thermoplastic resin, for example, such as ABS (acrylonitrile-butadiene-styrene copolymer) resin, AS (acrylonitrile-styrene copolymer) resin, polystyrene, polyvinyl chloride, polyolefin resin, acrylic resin, and polycarbonate resin, heat-melted to assume a liquid to fluidized state, or from, for example, an uncured liquid of two-component curable resin or catalyst curable resin, for example, such as urethane resin and polyester resin.

The film molded product 10A of the present embodiment also includes a terminal guide hole 27 that extends from the surface of the molded resin layer 22 to the surface of the metal wiring layer 15. This enables an electrical interconnection to outside.

### Film Molded Product Producing Method

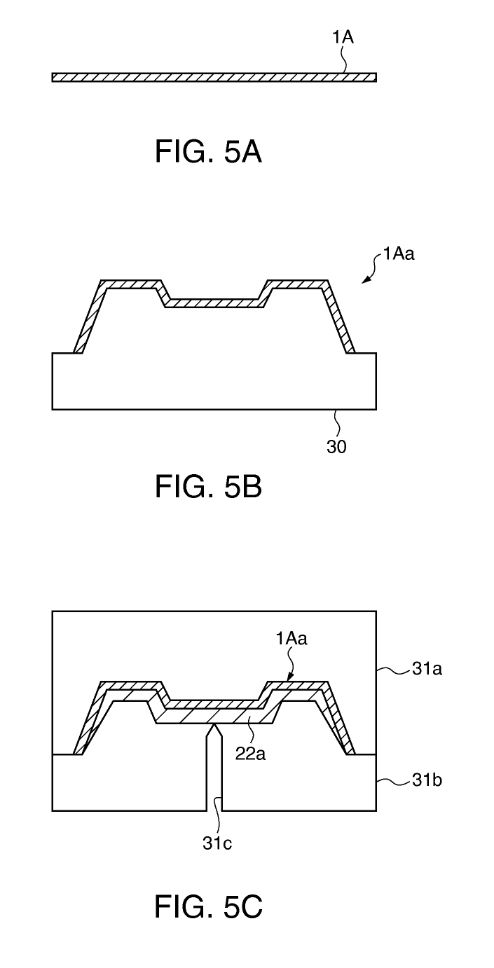

The film molded product producing method according to First Embodiment is described below. FIGS. 5A to 5C are step diagrams representing the film molded product producing method according to First Embodiment. The film molded product producing method of the present embodiment includes a molded resin layer forming step of forming the molded resin layer 22 by inmolding, using the film member 1A, as described below in detail.

First, as shown in FIG. 5A, the film member 1A is prepared. The producing method of the film member 1A is as described with reference to FIGS. 3A to 3D, and will not be described further.

Then, as shown in FIG. 5B, the film member 1A is molded. In the present embodiment, the film member 1A is vacuum-molded using a vacuum mold 30. Specifically, the film member 1A is placed on the vacuum mold 30 after being softened under heat, and the air is sucked through a vacuum hole (not illustrated) provided through the vacuum mold. As a result, a film member 1Aa is formed that conforms to the surface shape of the vacuum mold 30, as shown in FIG. 5B.

Thereafter, as shown in FIG. 5C, the vacuum-molded film member 1Aa is used to perform injection molding. Specifically, the vacuum-molded film member 1Aa is sandwiched between a first mold 31a and a second mold 31b for injection molding, and a molding resin is injected toward the film member 1Aa through a molding resin injection opening 31c. As a result, a molding resin 22a is charged into the film member 1Aa in the mold. After solidifying the molding resin 22a, the first mold 31a and the second mold 31b are released, and the molded product is separated from the injection mold. Note that the second mold 31b used for the injection molding has a vertical pin (not illustrated) in a manner allowing the tip of the vertical pin to contact the metal wiring layer 15 of the film member 1Aa upon sandwiching the film member 1Aa between the first mold 31a and the second mold 31b. The terminal guide hole 27 is formed as a result.

The film molded product 10A is formed after these steps (see FIG. 4).

First Embodiment has the following effects.

The film member 1A and the film molded product 10A include the decorative layer 12 and the metal wiring layer 15. While the decorative layer 12 provides visual decorative effects, the metal wiring layer 15 enables electrical interconnections, making it possible to improve the freedom of design. For example, in applications for the control panel of automobiles, the number of electric wires needed for routing can be reduced by connecting the electric wires to the electrical circuit pattern of the metal wiring layer 15 through the terminal guide hole 27 provided through the molded resin layer 22.

### Second Embodiment

### Configuration of Film Member

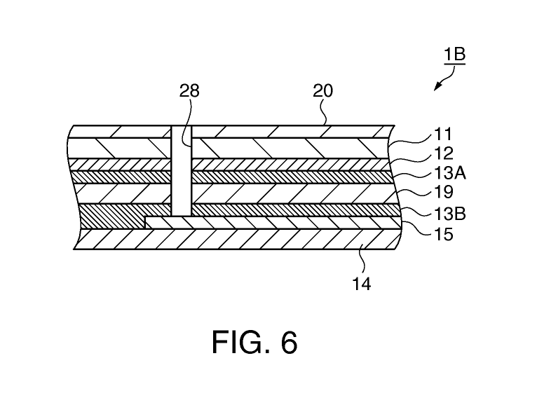

The configuration of the film member according to Second Embodiment is described below. FIG. 6 is a cross sectional view illustrating the configuration of the film member according to Second Embodiment. As illustrated in FIG. 6, a film member 1B includes a film layer 11, a decorative layer 12 having a predetermined image, a metal wiring layer 15 having a metal wiring, and a backing sheet 14 as a shape retaining layer.

More specifically, the film member 1B includes the film. layer 11, the decorative layer 12 formed on the film. layer 11, a first adhesive layer 13A formed on the decorative layer 12, a light-shielding layer 19 disposed on the first adhesive layer 13A, a second adhesive layer 13B formed on the light-shielding layer 19, the metal wiring layer 15 formed on the second adhesive layer 13B, and the backing sheet 14 formed on the metal wiring layer 15. In the present embodiment, a protective layer 20 that protects the film layer 11 is provided on the surface of the film layer 11. A terminal guide hole 28 is also provided that extends from the surface of the film layer 11 to the surface of the metal wiring layer 15. Because the protective layer 20 that protects the film layer 11 is provided on the surface of the film layer 11 in the present embodiment, the terminal guide hole 28 extends from the surface of the protective film 20 to the surface of the metal wiring layer 15.

The details of the film layer 11, the decorative layer 12, the metal wiring layer 15, and the backing sheet 14, including the forms of these members, are as described in First Embodiment, and will not be described further.

The light-shielding layer 19 is provided to prevent the patterns and colors of underlying layers such as the metal wiring layer 15 from being seen through when the decorative layer 12 is seen from the side of the protective film 20. The light-shielding layer 19 may be formed using, for example, ABS (acrylonitrile-butadiene-styrene copolymer) .

FIG. 2 is a schematic view illustrating an example of the metal wiring pattern of the film member according to First Embodiment. As illustrated in FIG. 2, a metal wiring 15a of the metal wiring layer 15 has a mesh shape (meshed). In this way, for example, the exerted stress by stretching can be relieved, and the metal wiring 15a can be prevented from breaking. Note that, for example, dimensions such as the width, thickness, the density of the mesh of the metal wiring 15a can be appropriately set, taking into account factors such as the position and the molded site of the metal wiring 15a.

### Film Member Producing Method

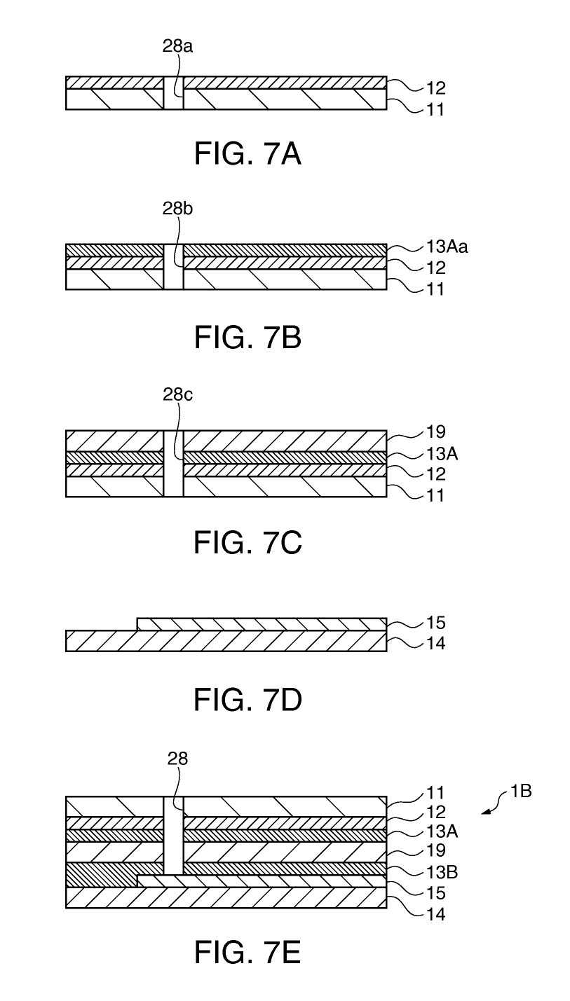

The film member producing method according to Second Embodiment is described below. FIGS. 7A to 7E are step diagrams representing the film member producing method according to Second Embodiment. As represented in FIGS. 7A to 7E, the film member producing method includes a decorative layer forming step of forming a predetermined image on the film layer, and a metal wiring layer forming step of forming a metal wiring. Each step is described below in detail.

In the decorative layer forming step (FIG. 7A), the decorative layer 12 is formed on the film layer 11 that has a through hole 28a formed at a predetermined position. For example, a functional liquid is applied onto the film layer 11 by being discharged toward the film layer 11 in droplets, using an inkjet method. The applied functional liquid is then solidified to form the decorative layer 12. Note that the method used to form the decorative layer 12 is not limited to an inkjet method, and, for example, methods such as gravure printing, letterpress printing, screen printing, and offset printing may be appropriately used.

In the adhesive coating step (FIG. 7B), a first adhesive 13Aa is applied onto the decorative layer 12. A through hole 28b is formed during this process.

Then, in the light-shielding layer forming step (FIG. 7C), the light-shielding layer 19 is formed on the first adhesive 13Aa, and the first adhesive 13Aa is solidified. As a result, the first adhesive layer 13A is formed, and the light-shielding layer 19 is formed on the first adhesive layer 13. A through hole 28c is formed during this process.

In addition to the adhesive coating step to the light-shielding layer forming step (FIGS. 7A to 7C), the following steps are performed.

In the metal wiring layer forming step (FIG. 7D), a metal wiring is formed on the backing sheet 14. For example, a conductive fine particle-containing functional liquid is applied onto the backing sheet 14 by being discharged in droplets, using an inkjet method. The applied functional liquid is then solidified to form the metal wiring. Alternatively, a carbon nanotube-containing functional liquid may be discharged in droplets, and solidified to form the metal wiring. Further, in the metal wiring layer forming step, the metal wiring 15a of a mesh shape may be formed, as illustrated in FIG. 2. Note that the method used to form the decorative layer 12 is not limited to the inkjet method, and, for example, methods such as gravure printing, letterpress printing, screen printing, offset printing, and flexography may be appropriately used.

Thereafter, as shown in FIG. 7E, the product formed in the adhesive coating step to the light-shielding layer forming step (FIGS. 7A to 7C) is bonded to the product formed in the metal wiring layer forming step (FIG. 7D) via a second adhesive 13Ba. The second adhesive 13Ba is then solidified to form the second adhesive layer 13B.

The film member 1B is formed after these steps (see FIG. 6).

### Configuration of Film Molded Product

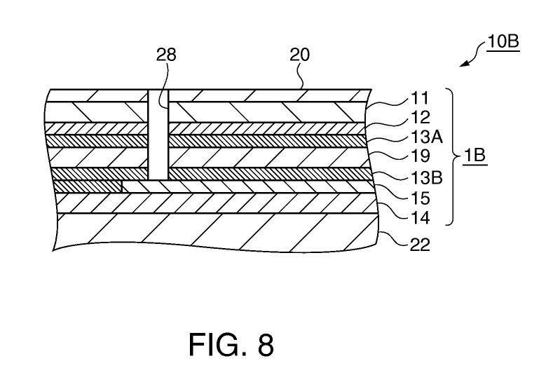

The configuration of the film molded product according to Second Embodiment is described below. FIG. 8 is a cross sectional view illustrating the configuration of the film molded product according to Second Embodiment. As illustrated in FIG. 8, a film molded product 10B includes the film member 1B, and a molded resin layer 22 inmolded with the film member 1B. In the present embodiment, the molded resin layer 22 is formed so as to cover the backing sheet 14. The configuration of the film member 1B is as described with reference to FIG. 6, and will not be described further.

The molded resin layer 22 is configured from thermoplastic resin, for example, such as ABS (acrylonitrile-butadiene-styrene copolymer) resin, AS (acrylonitrile-styrene copolymer) resin, polystyrene, polyvinyl chloride, polyolefin resin, acrylic resin, and polycarbonate resin, heat-melted to assume a liquid to fluidized state, or from, for example, an uncured liquid of two-component curable resin or catalyst curable resin, for example, such as urethane resin and polyester resin.

The film molded product 10B of the present embodiment also includes a terminal guide hole 28 that extends from the surface of the protective layer 20 to the surface of the metal wiring layer 15. This enables an electrical interconnection to outside through the terminal guide hole 28.

### Film Molded Product Producing Method

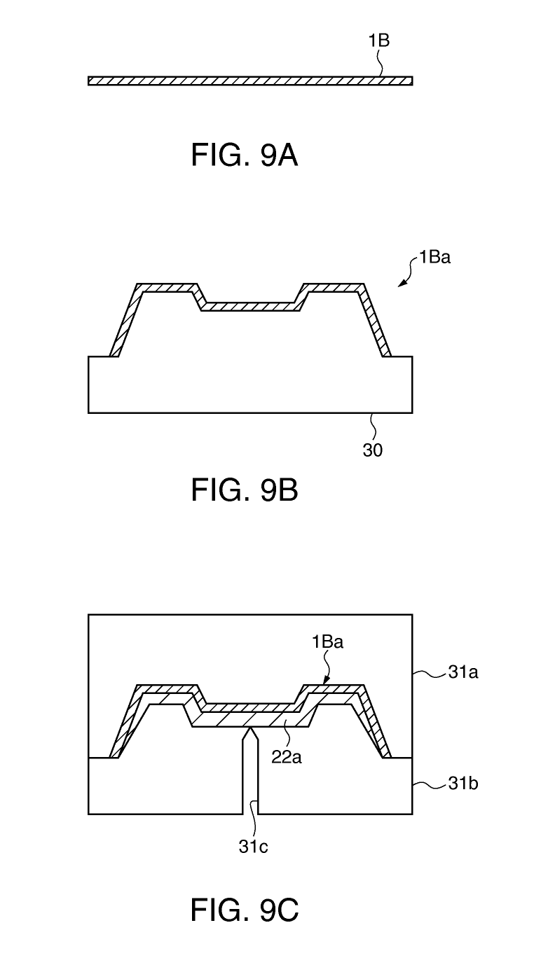

The film molded product producing method according to Second Embodiment is described below. FIGS. 9A to 9C are step diagrams representing the film molded product producing method according to Second Embodiment. The film molded product producing method of the present embodiment includes a molded resin layer forming step of forming the molded resin layer 22 by inmolding, using the film member 1B, as described below in detail.

First, as shown in FIG. 9A, the film member 1B is prepared. The producing method of the film member 1B is as described with reference to FIGS. 7A to 7E, and will not be described further.

Then, as shown in FIG. 9B, the film member 1B is molded. In the present embodiment, the film member 1B is vacuum-molded using a vacuum mold 30. Specifically, the film member 1B is placed on the vacuum mold 30 after being softened under heat, and the air is sucked through a vacuum. hole (not illustrated) provided through the vacuum mold. As a result, a film member 1Ba is formed that conforms to the surface shape of the vacuum mold 30, as shown in FIG. 9B.

Thereafter, as shown in FIG. 9C, the vacuum-molded film member 1Ba is used to perform injection molding. Specifically, the vacuum-molded film member 1Ba is sandwiched between a first mold 31a and a second mold 31b for injection molding, and a molding resin is injected toward the film member 1Ba through a molding resin injection opening 31c. As a result, a molding resin 22s is charged into the film member 1Ba in the mold. After solidifying the molding resin 22a, the first mold 31a and the second mold 31b are released, and the molded product is separated from the injection mold.

The film molded product 10B is formed after these steps (see FIG. 8) .

Second Embodiment has the following effects.

The film member 1B and the film molded product 10B include the decorative layer 12 and the metal wiring layer 15. While the decorative layer 12 provides visual decorative effects, the metal wiring layer 15 enables electrical interconnections, making it possible to improve the freedom of design. For example, in applications for the control panel of automobiles, the number of electric wires needed for routing can be reduced by connecting the electric wires to the electrical circuit pattern of the metal wiring layer 15 through the terminal guide hole 28 that extends from the surface of the protective film 20 to the metal wiring layer 15.

Note that the invention is not limited to the foregoing embodiments, and various modifications and improvements of the embodiments are possible. The following describes variations.

### Variation 1

The configuration of First Embodiment in which the terminal guide hole 27 is provided through the molded resin layer 22 (FIG. 4) is not restrictive. For example, other terminal guide hole may be formed that extends from the surface of the protective film 20 to the metal wiring 15a. In this way, more external electrical interconnections can be provided to further improve the freedom of design. Similarly, the configuration of Second Embodiment in which the terminal guide hole 28 is provided that extends from the surface of the protective film 20 to the metal wiring layer 15 (FIG. 8) is not restrictive. For example, other terminal guide hole may be formed that extends from the surface of the molded resin layer 22 to the metal wiring layer 15. In this way, more external electrical interconnections can be provided to further improve the freedom of design.

### Variation 2

The configuration of the foregoing embodiments in which the metal wiring layer 15 is used as an alternative to the electric wires is not restrictive. For example, the metal wiring layer 15 also can be appropriately used in applications such as in an antenna and an electromagnetic shield. In this way, the number of components can be reduced as above, and the freedom of design can be improved.

The entire disclosure of Japanese Patent Application No. 2011-056256, filed Mar. 15, 2011 is expressly incorporated by reference herein.

What is claimed is:

1. A film member comprising:
a film layer;
a decorative layer having a predetermined image;
a metal wiring layer having a metal wiring; and
a shape retaining layer.

2. The film member according to claim 1, comprising:
the film layer;
the decorative layer formed on the film layer;
an adhesive layer formed on the decorative layer;
the shape retaining layer disposed on the adhesive layer; and
the metal wiring layer formed on the shape retaining layer.

3. The film member according to claim 1, comprising:
the film layer;
the decorative layer formed on the film layer;
a first adhesive layer formed on the decorative layer;
a light-shielding layer formed on the first adhesive layer;
a second adhesive layer formed on the light-shielding layer;
the metal wiring layer formed on the second adhesive layer; and
the shape retaining layer formed on the metal wiring layer.

4. The film member according to claim 1, wherein the metal wiring layer is formed using a carbon nanotube.

5. The film member according to claim 1, wherein the metal wiring of the metal wiring layer has a mesh shape.

6. A film molded product comprising:
the film member of claim 1; and
a molded resin layer inmolded with the film member.

7. The film molded product according to claim 6, further comprising:
a terminal guide hole that extends from a surface of the molded resin layer to a surface of the metal wiring layer.

8. The film molded product according to claim 6, further comprising:
a terminal guide hole that extends from a surface of the film layer to a surface of the metal wiring layer.

9. A method for producing a film member, comprising:
forming a predetermined image on a film layer to form a decorative layer; and
forming a metal wiring to form a metal wiring layer.

10. A method for producing a film molded product, comprising:
forming a molded resin layer by inmolding, using the film member produced by the method of claim 9.
